(19) United States
(12) Patent Application Publication
(10) Pub. No.: US 2008/0029899 A1
(43) Pub. Date: Feb. 7, 2008

(54) Method of fabricating a semiconductor device and semiconductor device fabricated thereby

(76) Inventors: Du-heon Song, Yongin-si (KR); Ho-jin Oh, Seoul (KR); Tai-heui Cho, Suwon-si (KR); Joo-hyun Lee, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/712,504

(22) Filed: Mar. 1, 2007

(30) Foreign Application Priority Data
Aug. 4, 2006 (KR) 10-2006-0073913

(51) Int. Cl. H01L 21/4763

(52) U.S. Cl. 257/774; 438/637; 257/E21.495; 257/E23.141

(57) ABSTRACT

A method of fabricating a semiconductor device, including forming contact pads in a first insulating layer on a substrate, forming a second insulating layer on the first insulating layer and on the contact pads, forming bit lines on the second insulating layer, the bit lines connected to a first plurality of the contact pads by bit line contact plugs, forming expanded contact holes in the second insulating layer between the bit lines, wherein the expanded contact holes are expanded toward the bit lines, and forming contact spacers on side walls of the expanded contact holes.

### BACKGROUND OF THE INVENTION

1. Field of the Invention

The present invention relates to a method of fabricating a semiconductor device and a semiconductor device fabricated thereby. More particularly, the present invention relates to a method of fabricating a semiconductor device that may reduce or eliminate the occurrence of bridges between contacts, and a semiconductor device fabricated thereby.

2. Description of the Related Art

As the degree of integration of semiconductor devices increases, the size of contact holes for connecting devices and/or layers to each other may decrease while the thickness of an interlayer may increase. Therefore, an aspect ratio of the contact holes may increase, thus reducing an alignment margin of the contact hole during a photolithography process. The size of a buried contact (BC) serving as a storage node contact may also decrease, and the size thereof may become smaller from an upper part to a lower part. As a result, the contact hole may be incompletely formed.

In order to increase the size of the buried contact, the contact hole may be expanded, e.g., by performing a wet etching process on the contact hole after an initial formation of the contact hole. However, as the degree of integration of the semiconductor device increases, the size of a bit line may decrease. During the wet etching, a region of an insulating layer below the bit line may be removed, which may result in a conductive bridge being generated between the buried contacts adjacent to the bit line during a deposition of a conductive material for forming the buried contacts. Furthermore, a contact (DC) for connecting the bit line to a lower contact pad may be exposed during the wet etching process, which may result in a bridge being formed between the contact (DC) and the buried contact.

### SUMMARY OF THE INVENTION

The present invention is therefore directed to a method of fabricating a semiconductor device and semiconductor device fabricated thereby, which substantially overcome one or more of the problems due to the limitations and disadvantages of the related art.

It is therefore a feature of an embodiment of the present invention to provide a method of fabricating a semiconductor memory device having a reduced occurrence of conductive bridging between buried contacts, and a semiconductor device fabricated thereby.

It is therefore another feature of an embodiment of the present invention to provide a method of fabricating a semiconductor memory device having a reduced occurrence of conductive bridging between buried contacts and bit line contact plugs, and a semiconductor device fabricated thereby.

It is therefore yet another feature of an embodiment of the present invention to provide a method of fabricating a semiconductor memory device having a conductive spacer on a sidewall of an expanded contact hole.

At least one of the above and other features and advantages of the present invention may be realized by providing a method of fabricating a semiconductor device including forming contact pads in a first insulating layer on a substrate, forming a second insulating layer on the first insulating layer and on the contact pads, forming bit lines on the second insulating layer, the bit lines connected to a first plurality of the contact pads by bit line contact plugs, forming expanded contact holes in the second insulating layer between the bit lines, wherein the expanded contact holes are expanded toward the bit lines, and forming contact spacers on side walls of the expanded contact holes.

The second insulating layer may be formed by stacking a first oxide layer on the substrate, stacking an etching stop layer on the first oxide layer, and stacking a second oxide layer on the first oxide layer. Forming the expanded contact holes may include anisotropically etching the second insulating layer to expose a second plurality of contact pads, and isotropically etching the second insulating layer to form expanded portions in the first oxide layer, the first oxide layer having an isotropic etching rate higher than that of the second oxide layer. Forming the expanded contact holes may include anisotropically etching the second insulating layer to expose a second plurality of contact pads, and isotropically etching the second insulating layer to form expanded portions in the first oxide layer and the second oxide layer, the first oxide layer and the second oxide layer having a same isotropic etching rate. Forming the expanded contact holes may include anisotropically etching the second oxide layer and the etching stop layer to expose the first oxide layer, and isotropically etching the first oxide layer to form expanded portions in the first oxide layer, the first oxide layer having an isotropic etching rate higher than that of the second oxide layer. Forming the expanded contact holes may include anisotropically etching the second oxide layer and the etching stop layer to expose the first oxide layer, and isotropically etching the first oxide layer and the second oxide layer to form expanded portions in the first oxide layer and the second oxide layer, the first oxide layer and the second oxide layer having a same isotropic etching rate. Forming the expanded contact holes may include anisotropically etching the second oxide layer and the etching stop layer to expose the first oxide layer, and isotropically etching the second oxide layer to form expanded portions in the second oxide layer, the second oxide layer having an isotropic etching rate higher than that of the first oxide layer.

The second insulating layer may be formed by stacking a first oxide layer on the substrate and stacking a second oxide layer on the first oxide layer. Forming the expanded contact holes may include anisotropically etching the second insulating layer to expose a second plurality of contact pads, and isotropically etching the first oxide layer to form expanded portions in the first oxide layer, the first oxide layer having an isotropic etching rate higher than that of the second oxide layer. Forming the expanded contact holes may include anisotropically etching the second insulating layer to expose a second plurality of contact pads, and isotropically etching the second oxide layer to form expanded portions in the second oxide layer, the second oxide layer having an isotropic etching rate higher than that of the first oxide layer. Forming the expanded contact holes may include anisotropically etching the second oxide layer to expose the first oxide layer, and isotropically etching the first oxide layer to form expanded portions in the first oxide layer, the first oxide layer having an isotropic etching rate higher than that of the second oxide layer. Forming the expanded contact holes may include anisotropically etching the second oxide layer to expose the first oxide layer, and isotropically etching the second oxide layer to form expanded portions in the second oxide layer, the second oxide layer having an isotropic etching rate higher than that of the first oxide layer.

The contact spacers may be formed by depositing a conformal insulation layer on a portion of the second insulating layer exposed by the expanded contact holes. The method may further include forming a conductive material on contact spacers in adjacent first and second expanded contact holes, wherein forming the first and second expanded contact holes may include forming a void in a portion of the second insulating layer between the first and second contact holes such that first and second expanded contact holes are in communication, and forming the contact spacers may isolate the conductive material in the first expanded contact hole from the conductive material in the second expanded contact hole. The method may further include forming a conductive material on a contact spacer in an expanded contact hole, wherein forming the expanded contact hole may expose a portion of a bit line contact plug, and forming the contact spacer may isolate the bit line contact plug from the conductive material in the expanded contact hole.

At least one of the above and other features and advantages of the present invention may be realized by providing a semiconductor device including contact pads in a first insulating layer on a substrate, a second insulating layer on the first insulating layer and on the contact pads, bit lines on the second insulating layer, the bit lines connected to a first plurality of the contact pads by bit line contact plugs, expanded contact holes in the second insulating layer between the bit lines, wherein the expanded contact holes are expanded toward the bit lines, and contact spacers formed along side walls of the expanded contact holes.

The second insulating layer may include an oxide layer, and the expanded contact holes may include expanded portions extending toward the bit lines in the oxide layer. The contact spacers may include a conformal insulation layer on the expanded portions. The device may further include a conductive material in the expanded contact holes, wherein the contact spacers are disposed between the conductive material and the side walls of the expanded contact holes. The second insulating layer may include at least two layers having different isotropic etching rates.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a layout of a semiconductor device according to an embodiment of the present invention;

FIGS. 2-6 illustrate cross-sectional views according to embodiments of the present invention, and correspond to cross-sections taken along a line II-II′ of FIG. 1; and

FIGS. 7A-13E illustrate cross-sectional views of stages in a method of fabricating a semiconductor device according to embodiments of the present invention.

### DETAILED DESCRIPTION OF THE INVENTION

Korean Patent Application No. 10-2006-0073913, filed on Aug. 4, 2006, in the Korean Intellectual Property Office, and entitled: “Method of Fabricating Semiconductor Device and Semiconductor Device Fabricated Thereby,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

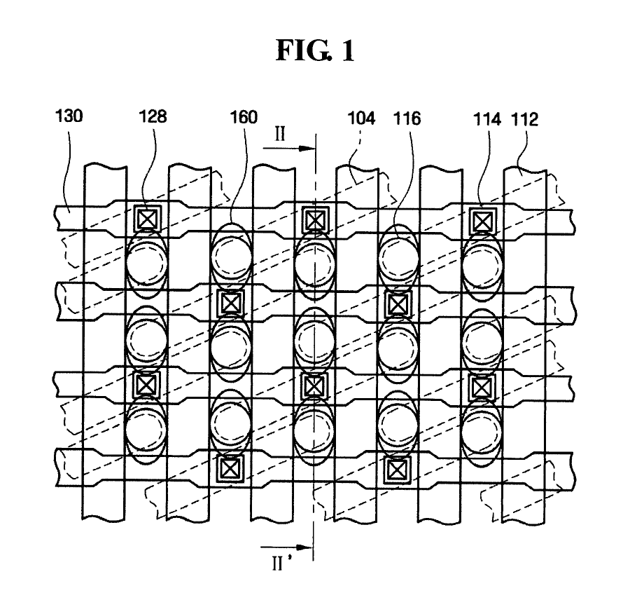

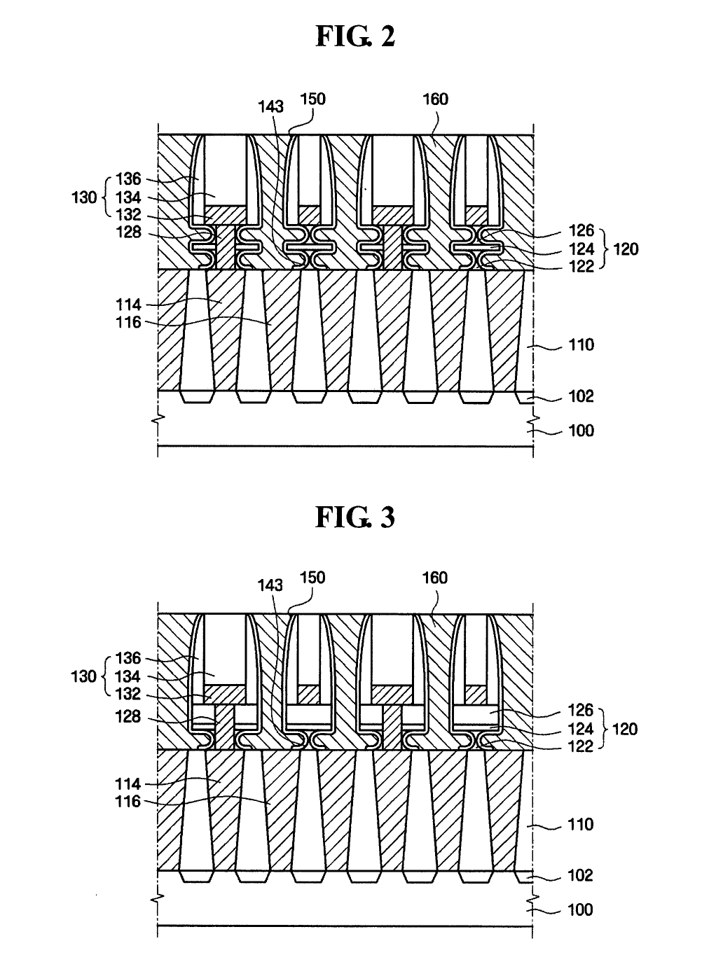

FIG. 1 illustrates a layout of a semiconductor device according to an embodiment of the present invention, and FIGS. 2-6 illustrate cross-sectional views according to embodiments of the present invention, and correspond to cross-sections taken along a line II-II′ of FIG. 1.

Referring to FIGS. 1 and 2-6, a substrate 100, e.g., a semiconductor substrate, may include a plurality of active regions 104 defined therein by element isolation layers 102. A number of gate lines 112 may be located on the substrate 100 and may extend in a first direction. Impurity regions (not shown) may be formed in the active regions 104 provided across the gate lines 112. The gate lines 112 may respectively include a gate insulating layer, a gate conductive layer, a gate capping layer and a spacer (not shown).

A first interlayer insulating layer 110 may be disposed on the gate lines 112.

Contact pads 114 and 116 may be disposed in the first interlayer insulating layer 110 and located between the gate lines 112. The contact pads 114 may be bit line contact pads, and the contact pads 116 may be storage node contact pads 116. The contact pads 114 and 116 may be formed of a conductive material, e.g., polysilicon doped with an impurity, a metallic material, etc. The impurity region (not shown), a bit line 130, and a storage node (not shown) may be electrically connected to each other.

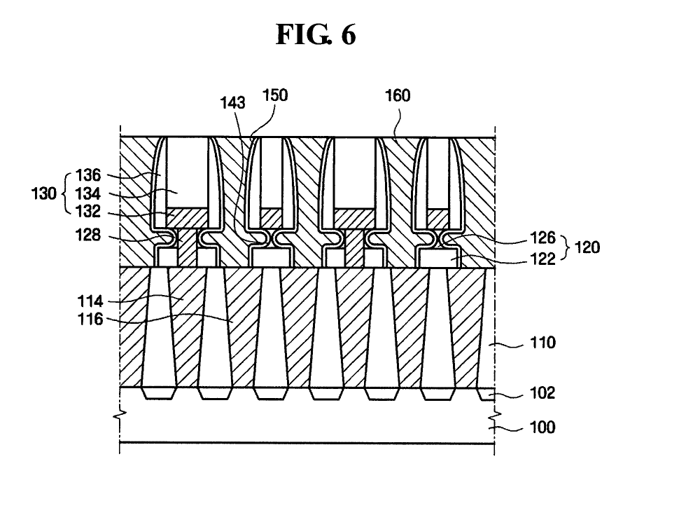

A second interlayer insulating layer 120 may be disposed on the first interlayer insulating layer 10, and a bit line contact plug 128 may be disposed in the second interlayer insulating layer 120 so as to be electrically connected to the bit line contact pad 114. The second interlayer insulating layer 120 may have a multilayer structure, e.g., a stack of insulating layers having different wet etching rates. In an implementation, as shown in FIGS. 2-4, the second interlayer insulating layer 120 may have a stacked structure of a first oxide layer 122, an etching stop layer 124, and a second oxide layer 126. In another implementation, as shown in FIGS. 5 and 6, the second interlayer insulating layer 120 may have a stacked structure of the first oxide layer 122 and the second oxide layer 126.

In detail, the second interlayer insulating layer 120 may have a multilayer structure in which wet etching rates of insulating layers that are adjacent to each other are different. The wet etching rates of insulating layers located at the top and bottom of the multilayer structure, i.e., above and below another insulating layer having a wet etching rate different thereto, may be equal to each other. For example, the first oxide layer 122, the etching stop layer 124, and the second oxide layer 126 may be formed of materials having the different wet etching rates, respectively, or, where the stacked structure includes the first oxide layer 122/etching stop layer 124/second oxide layer 126, the first oxide layer 122 and the second oxide layer 126 may be formed of material(s) having a same wet etching rate.

The first oxide layer 122 and the second oxide layer 126 may be formed of a material such as a silicon oxide-type material, e.g., BPSG (BoroPhosphoSilicate Glass), PE-TEOS (Plasma Enhanced Tetra Ethyl Ortho Silicate), HDP (High Density Plasma), etc. The etching stop layer 124 may be formed of, e.g., a silicon nitride layer, a silicon oxynitride layer, etc.

It will be appreciated that embodiments of the present invention may include not only the stacked structures of two layers or three layers described above, but also stacked structure of three layers or more formed of insulating layers having different etching rates.

A number of bit lines 130 may be formed on the second interlayer insulating layer 120 and may extend in a direction crossing the gate lines 112, e.g., in a direction perpendicular to the gate lines 112. A bit line 130 may be connected to a bit line contact plug 128. The bit line 130 may include a stack of a bit line conductive layer 132 and a bit line capping layer 134, and a spacer 136 may be located at a side wall. The bit line conductive layer 132 may include, e.g., a barrier metal layer and a metal layer.

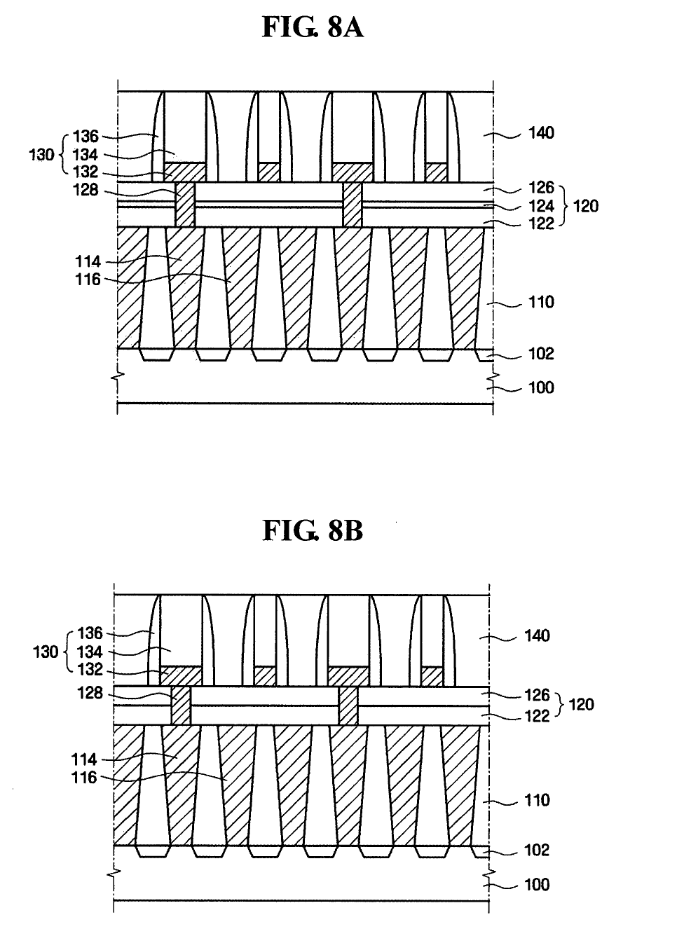

A third interlayer insulating layer 140 (see, FIGS. 8A and 8B) may be disposed on the bit line 130, and expanded contact holes 144 (referred to as 144a, 144b, 144c, 144d, and 144e) may be formed in the second and third interlayer insulating layers 120 and 140 so as to expose lower storage node contact pads 116. The expanded contact holes 144 may each include at least one expanded portion 143. The expanded portion 143 may be expanded toward the bit lines 130 in the second interlayer insulating layer 120, i.e., expanded laterally in the drawing figures.

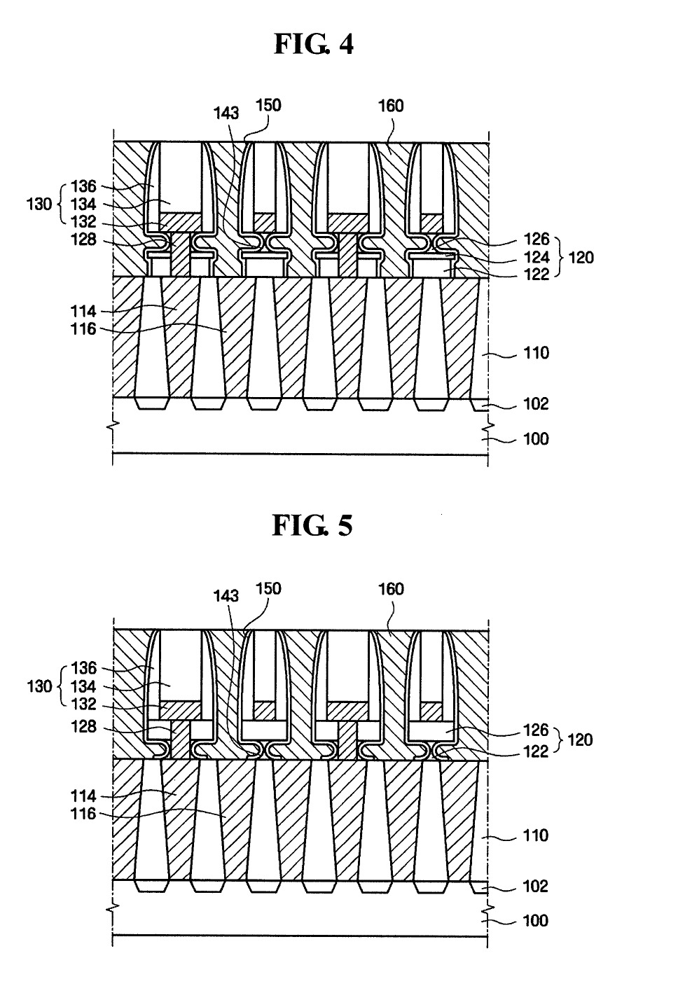

The expanded portions 143 will be described in detail with reference to FIGS. 2-6. Referring to FIGS. 2-4, when the second interlayer insulating layer 120 includes the first oxide layer 122, the etching stop layer 124, and the second oxide layer 126, as shown in FIG. 2, the expanded portions 143 may be formed in the first and second oxide layers 122 and 126, respectively. In addition, as shown in FIG. 3, the expanded portions 143 may be formed in the lower first oxide layer 122, or, as shown in FIG. 4, in the second oxide layer 126. As shown in FIG. 3, if the expanded portions are formed in the second oxide layer 126, a side-wall profile of the expanded contact holes 144 in the first oxide layer 122 may be expanded relative to the side-wall profile of the second oxide layer 126. This may provide an increased area for contacting to the storage node contact pad 116.

As shown in FIGS. 5 and 6, if the second interlayer insulating layer 120 includes the first oxide layer 122 and the second oxide layer 126, the expanded portions 143 may be formed in the first oxide layer 122 as shown in FIG. 5, or formed in the second oxide layer 126 as shown in FIG. 6.

Referring again to FIGS. 2-6, a contact spacer 150 may be formed at the inner wall, i.e., the side wall, of the expanded contact holes 144. The contact spacer 150 may prevent the bit line contact plug 128 and/or the bit line contact pad 114 from being exposed by the expanded contact holes 144. A storage node contact 160 formed of conductive material, e.g., a metallic material, may be disposed in the expanded contact holes 144 in which the contact spacer 150 is formed. The storage node contact 160 in the expanded contact holes 144 may have an increased contact area with the storage node contact pad 116. The contact spacer 150 may prevent formation of a conductive bridge under the bit line 130 between storage node contacts 160, or between a storage node contact 160 and a bit line contact plug 128.

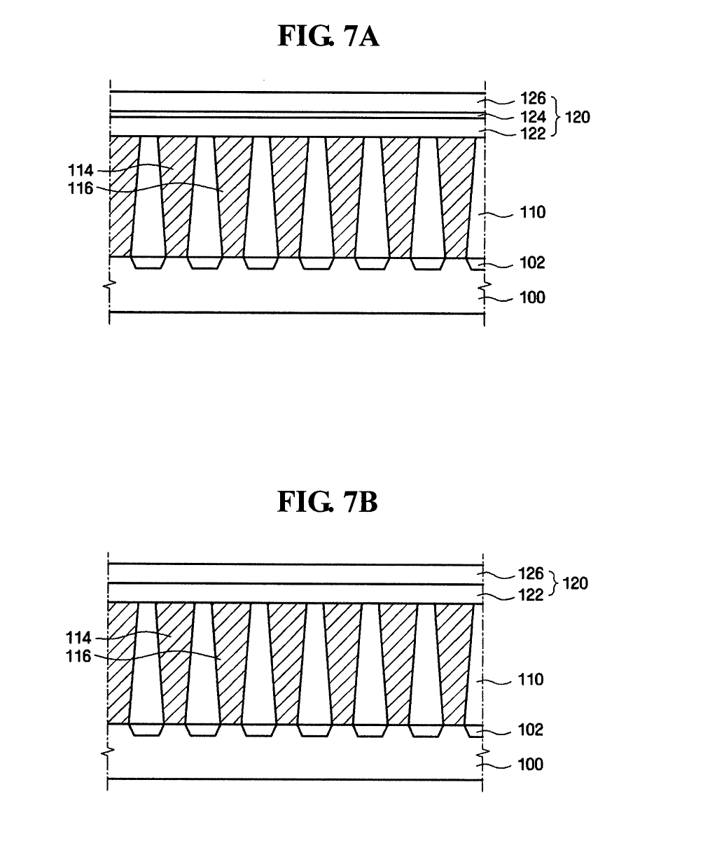

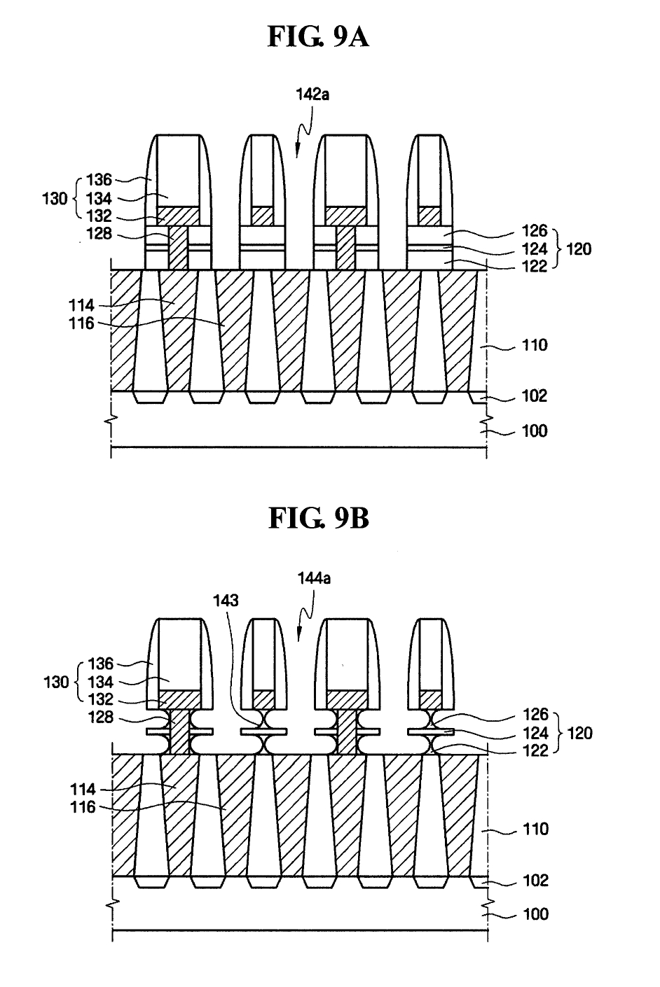

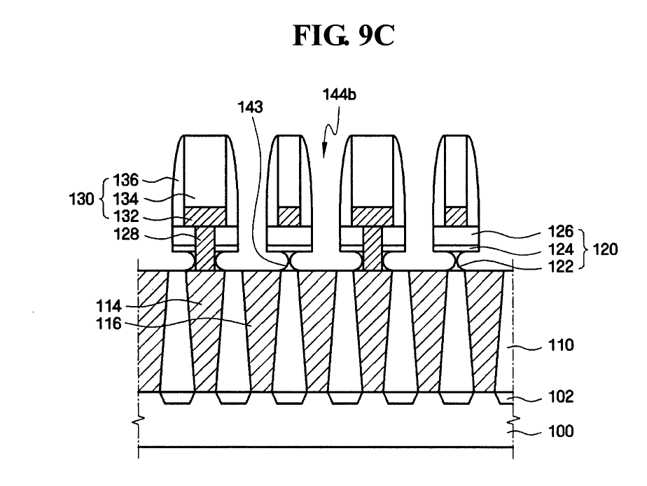

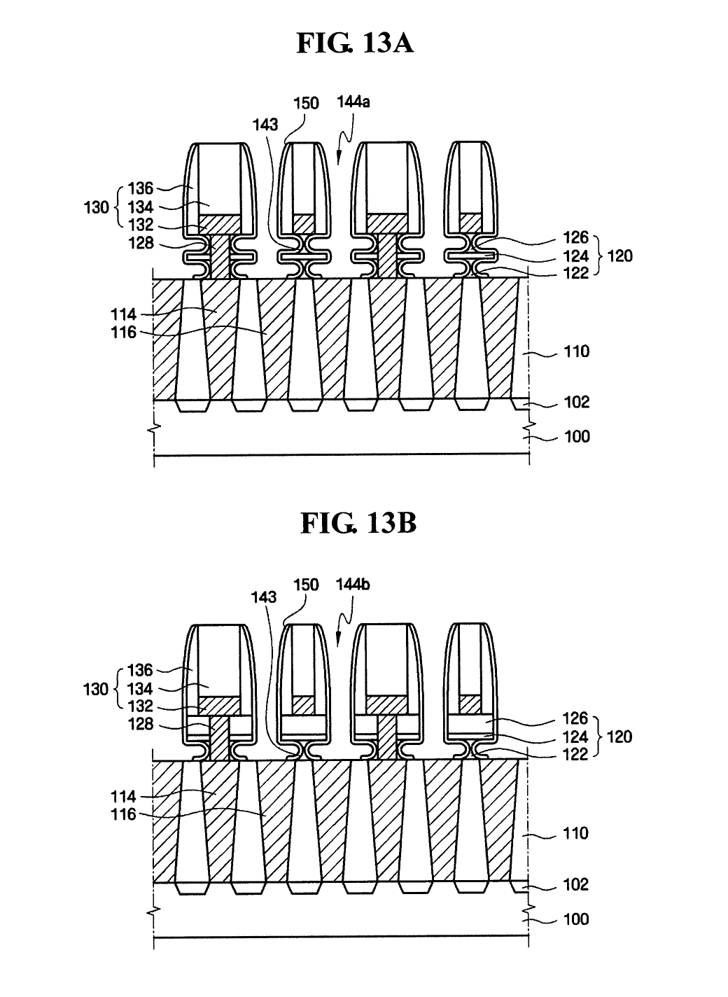

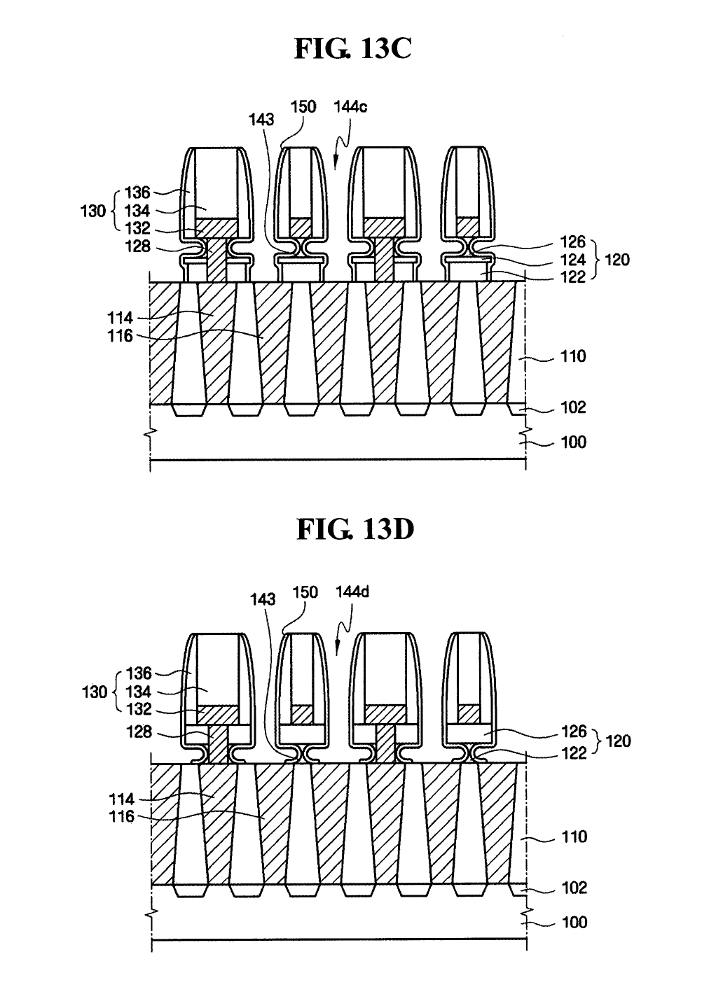

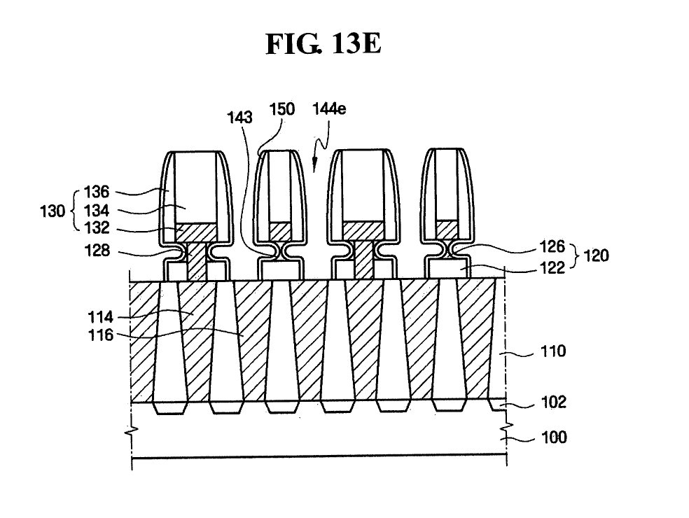

Hereinafter, a method of fabricating a semiconductor device according to embodiments of the invention will be described with reference to FIGS. 7A-13E, which illustrate cross-sectional views of stages in a method of fabricating a semiconductor device according to embodiments of the invention. FIGS. 9A to 12C illustrate cross-sectional views of stages in a method of forming the expanded portion of the semiconductor device.

As shown in FIGS. 7A and 7B, an element isolation layer 102 defining field regions and active regions 104 may be formed, e.g., by a LOCOS (Local Oxidation of Silicon) process, a STI (Shallow Trench Isolation) process, etc.

A number of gate lines 112 may be formed on the substrate 100. The gate lines 112 may extend in a first direction and may cross the active regions 104. The gate lines 112 may be formed by, e.g., stacking and patterning a gate insulating layer (not shown), a gate conductive layer (not shown), and a gate capping layer (not shown) on the substrate 100, and forming a spacer (not shown) at both side walls.

An impurity region (not shown) may be formed by doping or injecting an impurity into the active regions 104 at sides of the gate line 112, e.g., using an ion injection mask. A general transistor may be formed by the above-described process.

Next, an insulating material may be deposited on the substrate 100 in which the gate lines 112 are formed, e.g., across the entire surface of the substrate 100, and a first interlayer insulating layer 110 may be formed by planarizing the upper part, e.g., by a chemical mechanical polishing (CMP) process, an etch back process, etc.

A contact hole that exposes the impurity region (not shown) in the substrate 100 may be formed in the first interlayer insulating layer 110 by a general photolithography process. Where the contact hole is formed in a first interlayer insulating layer 110 that is formed of a silicon oxide, the contact hole may be self-aligned to the gate line 112 by using an etching gas having a high etching selectivity with respect to the gate line 112, thus exposing the impurity region (not shown) in the substrate 100.

A conductive layer may be formed by depositing a conductive material, e.g., a metallic material, a polysilicon doped with an impurity, etc., on the entire surface of the first interlayer insulating layer 110 in which the contact holes are formed. The conductive layer may then be planarized until an upper part of the first interlayer insulating layer 110 is exposed, thereby forming contact pads 114 and 116, which may be self-aligned, in the first interlayer insulating layer 110. The contact pads 114 and 116 may be, respectively, a bit line contact pad 114 and a storage node contact pad 116.

A second interlayer insulating layer 120 may be formed on the first interlayer insulating layer 110 and the contact pads 114 and 116, e.g., by depositing and planarizing an insulating material layer. The second interlayer insulating layer 120 may be formed by stacking insulating layers having different wet etching rates in a multi-layer structure. The second interlayer insulating layer 120 may be formed such that the wet etching rates of the insulating layers adjacent to each other are different. The wet etching rate of insulating layers located above and below an insulating layer having a wet etching rate different thereto may be equal to each other. For example, as shown in FIG. 7A, the second interlayer insulating layer 120 may be formed by stacking a first oxide layer 122, an etching stop layer 124, and a second oxide layer 126. The first oxide layer 122 and the second oxide layer 126 may be formed of a material having a same wet etching rate. In another implementation, as shown in FIG. 7B, the second interlayer insulating layer 120 may be formed by stacking the first oxide layer 122 and the second oxide layer 126, which may have different wet etching rates.

The second interlayer insulating layer 120 may have a thickness of about 1000 Å to about 1200 Å. Where the stacked structure includes the first oxide layer 122/etching stop layer 124/second oxide layer 126, the first oxide layer 122 may be formed to a thickness of about 500 Å or less, and the etching stop layer 124 may be formed to a thickness of about 300 Å or less.

The first oxide layer 122 and the second oxide layer 126 may be formed of a material such as a silicon oxide-type material, e.g., BPSG, PE-TEOS, HDP, etc. The etching stop layer 124 may be formed of, e.g., a nitride layer such as a silicon nitride layer, a silicon oxynitride layer, etc.

Next, as shown in FIGS. 8A and 8B, bit line contact holes that expose the lower bit line contact pads 114 may be formed in the second interlayer insulating layer 120 by a general photolithography process. Then, the bit line contact plugs 128 may be formed in the second interlayer insulating layer 120, e.g., by depositing and planarizing a conductive material. The bit line contact plugs 128 may be electrically connected to the impurity regions of the substrate 100.

After the bit line contact plugs 128 are formed, a number of bit lines 130 may be formed on the second interlayer insulating layer 120. The bit lines 130 may extend in a direction crossing the lower gate lines 112, e.g., perpendicular thereto, and may be electrically connected to the bit line contact plugs 128. The bit lines 130 may be formed by stacking and patterning a bit line conductive layer 132 and a bit line capping layer 134, and forming a spacer 136 at the side wall. The bit line conductive layer 132 may be formed by, e.g., stacking a barrier metal layer and metal layer.

After the bit lines 130 are formed, a third interlayer insulating layer 140 may be formed, e.g., by depositing and planarizing an insulating material that covers the bit lines 130 on the entire surface of the substrate 100.

Next, the expanded contact holes 144 having at least one of the expanded portions 143 may be formed in the second interlayer insulating layer, e.g., by isotropically etching after partially anisotropically etching the second and third interlayer insulating layers 120 and 140. The expanded portions 143 may be formed in both the first oxide layer 122 and the second oxide layer 126, formed in the first oxide layer 122, formed in the second oxide layer 126, etc.

In an implementation, the expanded contact holes 144 may be formed as follows. Referring to FIG. 9A, a mask (not shown) may be formed on the third interlayer insulating layer 140 so as to expose the lower storage node contact pad 116. Then, an opening 142a that exposes the lower storage node contact pad 116 may be formed by selectively anisotropically etching, e.g., dry etching, the second and the third interlayer insulating layers 120 and 140 using the mask. The opening 142a may be self-aligned to the bit line 130 using the dry etching process, and using the bit line capping layer 134 of the bit line 130 as a mask.

The opening 142a exposing the storage node contact pad 116 may be treated by a wet etching process. Where the first oxide layer 122 and the second oxide layer 126, having side walls exposed by the opening 142a, are formed of material(s) having a same wet etching rate, the first oxide layer 122 and the second oxide layer 126 below the bit line 130 may be etched by wet etching so as to have rounded side wall profiles, as shown in FIG. 9B. During the wet etching process for etching the first oxide layer 122 and the second oxide layer 124 in the expanded portion 143, the etching stop layer 124 may serve as a wet etch barrier. Therefore, even though the first and second oxide layers 122 and 124 below the bit line 130 may be locally removed by the formation of the expanded portion 143, the etching stop layer 124 may remain. Thus, as shown in FIG. 9B, the expanded contact hole 144a may extend in the first oxide layer 122 and the second oxide layer 126, and the expanded contact hole 144a may have the expanded portion 143 expanded toward the bit line 130.

Where the first oxide layer 122 is formed of a material having a wet etching rate higher than the wet etching rate of the second oxide layer 126, the first oxide layer 122 may be isotropically etched during the wet etching process of the opening 142a and may be expanded toward the bit line 130 within the first oxide layer 122. Thus, as shown in FIG. 9C, the expanded contact hole 144b having the expanded portion 143 may extend in the first oxide layer 122.

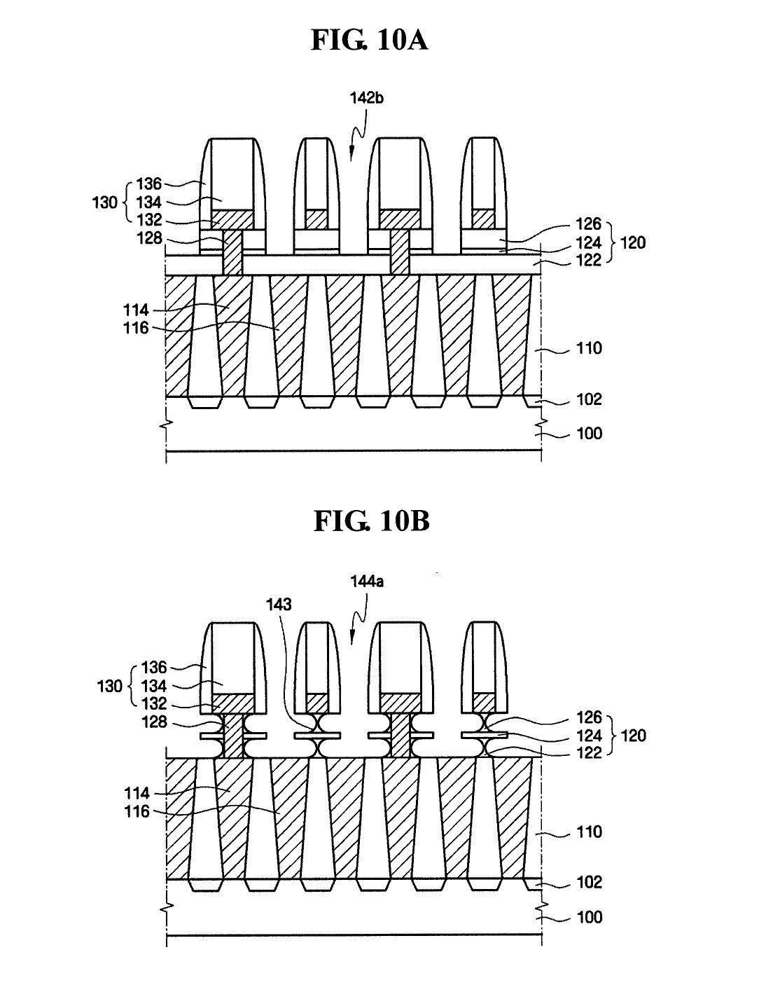

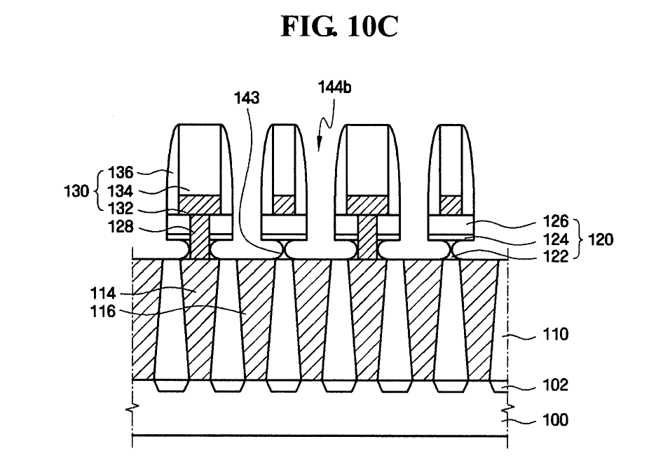

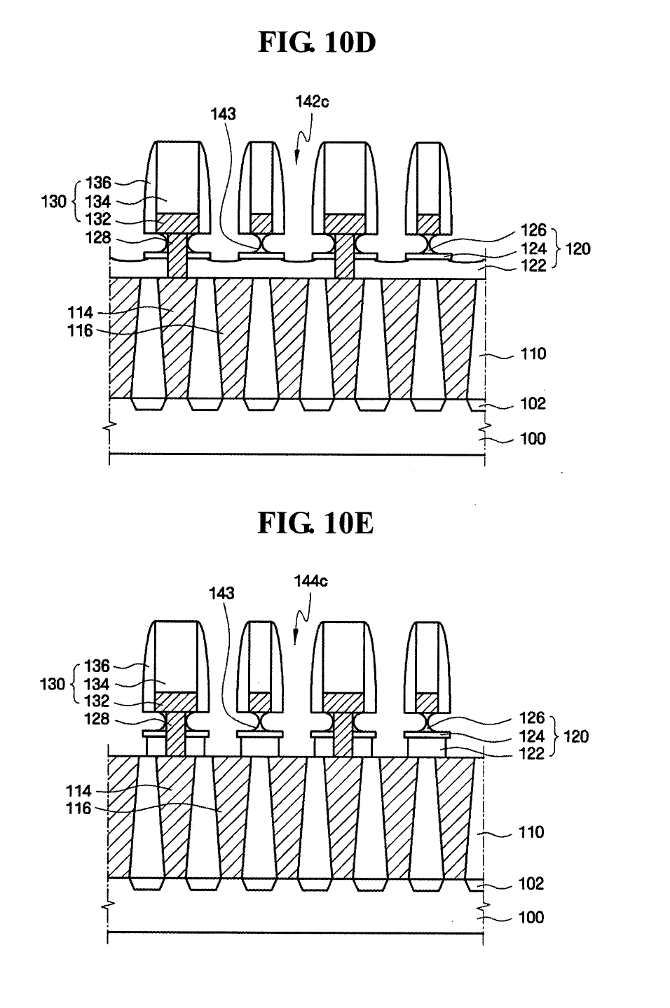

Another method of forming the expanded contact hole 144 will be described in detail with reference to FIGS. 10A-10E. First, as shown in FIG. 10A, an opening 142b may be formed by selectively dry etching a portion of the third interlayer insulating layer 140 and the second interlayer insulating layer 120 until the surface of the first oxide layer 122 is exposed. The opening 142b may be formed by using the bit line capping layer 134 as the mask during the dry etching process so as to be self-aligned to the bit line 130. During the dry etching process for forming the opening 142b that exposes the first oxide layer 122, the etching may be stopped by the etching stop layer 124. Over-etching may remove the etching stop layer 124.

After the opening 142b is formed, the expanded portion 143 may be formed in both the first oxide layer 122 and/or the second oxide layer 126 using the wet etching process. Where the first oxide layer 122 and the second oxide layer 126 have the same wet etching rate, the first oxide layer 122 and the second oxide layer 126 may be isotropically etched toward the bit line 130 to form the expanded portion 143 having a rounded side-wall profile. In addition, the wet etching of the first oxide layer 122 may expose the lower storage node contact pad 116 and may expand the opening toward the bit line 130, thus forming the expanded portion 143. As shown in FIG. 10B, it may form the expanded contact hole 144a in which the expanded portion 143 may extend in each of the first oxide layer 122 and the second oxide layer 126. The etching stop layer 124 below the bit line 130 may not be wet etched and may remain.

Where the wet etching rate of the first oxide layer 122 is higher than that of the second oxide layer 126, if the opening exposing the first oxide layer 122 is wet etched, as shown in FIG. 10C, the first oxide layer 122 may be etched and the lower storage node contact pad 116 may be exposed. The expanded portion 143 may extend toward the bit line 130. Accordingly, it may form the expanded contact hole 144b that increases an exposed area of the storage node contact pad 116.

A method of forming an expanded contact hole 144c will be described for a case where the second oxide layer 126 is formed of a material having a wet etching rate higher than that of the first oxide layer 122. First, the opening 142b, which exposes the first oxide layer 122, may be formed as described above in connection with FIG. 10A and then wet etched. Since the wet etching rate of the second oxide layer 126 may be high, the expanded portion 143 may be expanded toward the bit line 130 in the second oxide layer 126, as shown in FIG. 10D. When the second oxide layer 126 is wet etched, the surface of the first oxide layer 122 may also be partially isotropically etched.

Then, as shown in FIG. 10E, the expanded contact hole 144c may be formed by dry etching the first oxide layer 122 without a separate mask for the opening 142c. Since the surface of the first oxide layer 122 may have been partially isotropically etched by the wet etch process, the expanded contact hole 144c may be formed such that the size of the expanded contact hole 144c in the first oxide layer 122 is larger than that of the expanded contact hole 144c in the etching stop layer 124. When the expanded contact hole 144c is formed as described above, the expanded portion 143 may be formed in the second oxide layer 126. The expanded portion 143 may be dry etched so as to generally follow the side wall profile produced by the wet etching process. Thus, the exposed area of the storage node contact pad 116 may be increased while preventing the lower portion of the bit line contact plug 128 from being exposed by the expanded contact hole 144c.

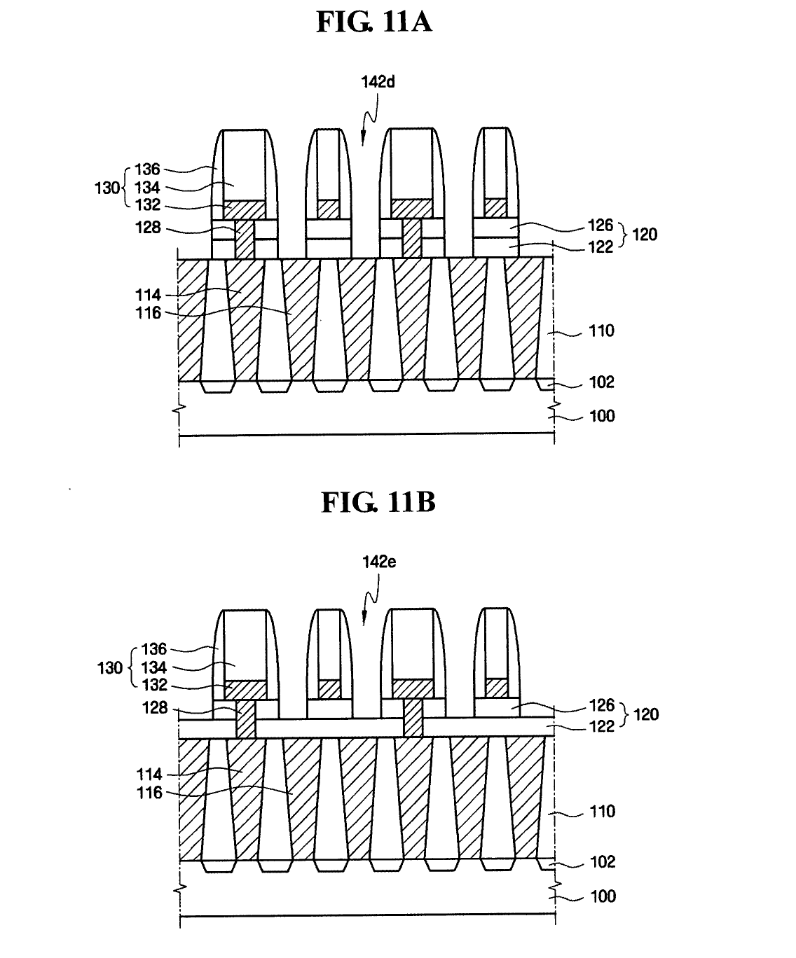

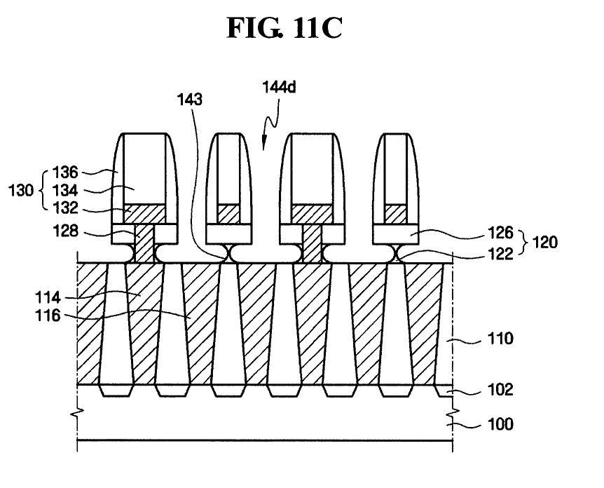

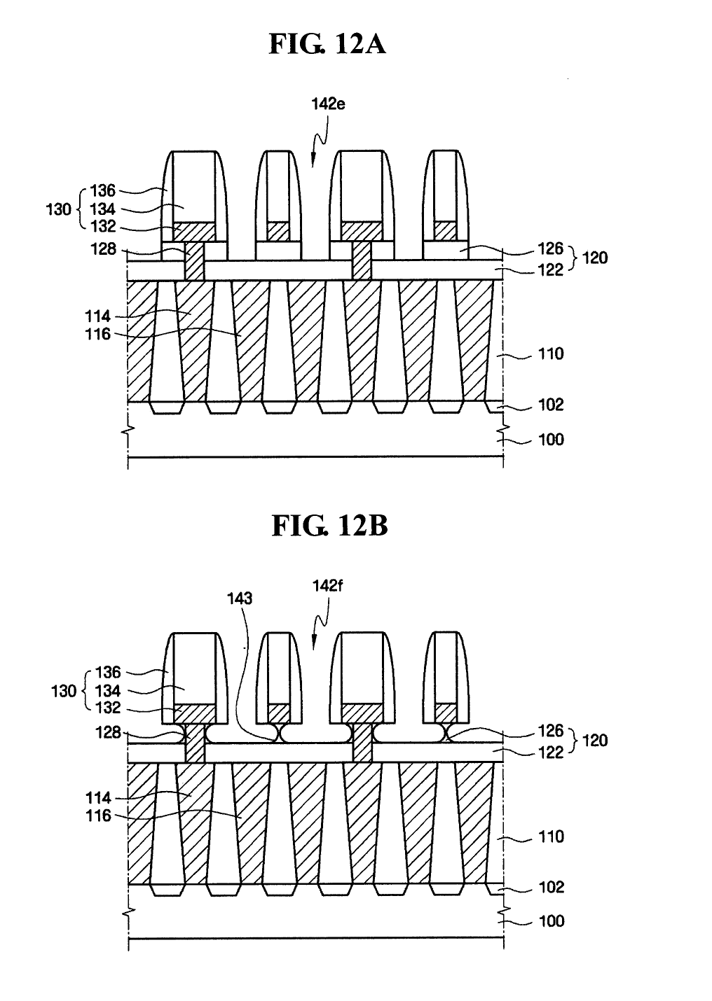

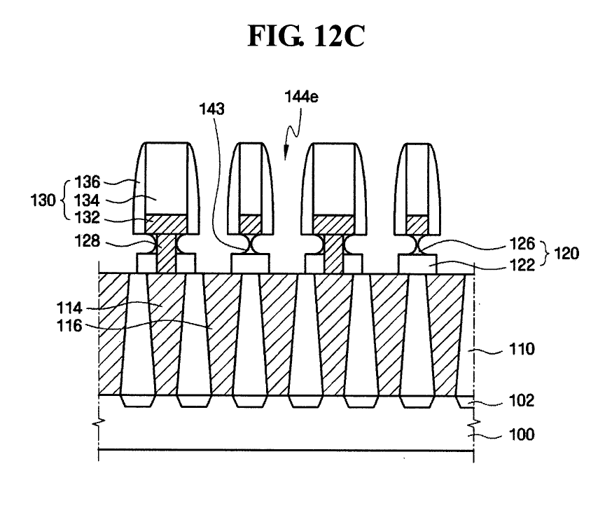

A method of forming expanded contact holes 144d and 144e in a structure having the first oxide layer 122 and the second oxide layer 126 stacked will be described with reference to FIGS. 11A-11C and 12A-12C. First, where the wet etching rate of the first oxide layer 122 is high, a mask (not shown) may be formed on the third interlayer insulating layer 140 covering the bit line 130 so as to expose the lower storage node contact pad 116. Then, as shown in FIG. 11A, an opening 142d, which exposes the lower storage node contact pad 116, may be formed by selectively dry etching the second and third interlayer insulating layers 120 and 140 using the mask. In another implementation, as shown in FIG. 11B, an opening 142e exposing the lower first oxide layer 122 may be formed. The openings 142d and 142e may be self-aligned to the bit line 130 by the dry etching process and using the bit line capping layer 134 of the bit line 130 as a mask.

Next, the opening 142d exposing the storage node contact pad 116, or the opening 142e exposing the first oxide layer 122, may be treated by the wet etching process. Where the wet etching rate of the first oxide layer 122 is high, the expanded contact hole 144d having the expanded portion 143 may be formed in the first oxide layer 122, as shown in FIG. 11C. When the opening 142d exposing the storage node contact pad 116 is wet etched, the expanded portion 143, which is expanded toward the bit line 130, may be formed in the first oxide layer 122. In addition, when the opening 142e exposes the first oxide layer 122, the lower and side surface of the first oxide layer 122 may be isotropically etched and the etching may expose the lower storage node contact pad 116. Thus, the first oxide layer 122 may be expanded laterally.

A method of forming the expanded contact hole 144 will be described in detail with reference to FIGS. 12A to 12C. The first oxide layer 122 of the second interlayer insulating layer 120 may be formed of a material having a wet etching rate that is lower than that of the second oxide layer 126. The opening 142e may be formed by selectively dry etching the second and third interlayer insulating layers 120 and 140, as shown in FIG. 12A. The opening 142e may be self-aligned to the bit line 130 and may expose the second oxide layer 126. Next, as shown in FIG. 12B, the expanded opening 142f having the expanded portion 143 may be formed in the second oxide layer 126 by wet etching the opening 142e.

Then, as shown in FIG. 12C, the expanded contact hole 144e that exposes the lower storage node contact pad 116 may be formed by dry etching the first oxide layer 122 exposed by the expanded opening 142f. By dry etching the first oxide layer 122 through the expanded opening 142f, the diameter of the expanded contact hole 144e in the first oxide layer 122 may be increased relative to the diameter of the opening 142f. That is, the expanded portion 143 may be formed in the second oxide layer 126, and the first oxide layer 122 may be dry etched so as to be connected to the side-wall profile formed by the wet etching process. Thus, the exposed area of the storage node contact pad 116 may increase while the lower portion of the bit line contact plug 128 may be prevented from being exposed by the expanded contact hole 144e.

Examples of the etchants that may be suitable for the isotropic etching that forms the expanded portions 143 may include, e.g., ammonium hydroxide (NH₄OH), a peroxide such as hydrogen peroxide (H₂O₂), a mixture of de-ionized water and hydrofluoric acid (HF) solution, etc. The first oxide layer 122 and/or the second oxide layer 126 located below the bit line 130 may be locally removed during the isotropic etching process for expanding the expanded portion 143 toward the bit line 130.

As described above, the expanded portions 143 may be formed in the second interlayer insulating layer 120 by various methods. Accordingly, the lower area of the expanded contact holes 144a, 144b, 144c, 144d, and 144e that expose the storage node contact pad 116 may be increased.

After the expanded contact holes 144 are formed, the contact spacer 150 may be formed at the inner wall of the expanded contact holes 144. A spacer insulating layer (not shown) may be conformally formed on the entire surface of the structure having the expanded contact holes 144. The spacer insulating layer may be formed, e.g., by depositing silicon nitride (SiN), so as to have the thickness of about 100 Å to about 300 Å. Then, the contact spacer 150 may be formed at the inner wall of the expanded contact holes 144 by selectively removing the spacer insulating layer, e.g., by an etch back process.

It will be appreciated that where the first and second oxide layers 122 and 126 below the bit line 130 are locally removed, adjacent expanded contact holes 144 may be connected to each other. However, by conformally depositing the spacer insulation layer on the etching stop layer 124 that remains, separation of the adjacent expanded contact holes 144 may be effected.

Further, even if the bit line contact plug 128 is exposed by the expanded portion 143 of the expanded contact holes 144, the spacer insulating layer may be conformally deposited along the exposed surface of the bit line contact plug 128. Accordingly, the bit line contact plug 128 may be electrically insulated from a storage node contact 160 in the adjoining expanded contact hole 144.

Referring again to FIGS. 2-6, the storage node contact 160 may be formed by filling the expanded contact holes 144 with a conductive material such as a metallic material. After the conductive material is formed on the substrate 100, the conductive material may be planarized, e.g., removed to the level of the bit line capping layers 134.

A conductive bridge under the bit line 130 between storage node contacts 160 may be prevented by the contact spacer 150 on the inner walls of the expanded contact holes 144. In addition, the contact spacer 150 may prevent a conductive bridge between the storage node contact 160 and the bit line contact plug 128.

As described above, according to embodiments of the present invention, storage node contacts formed in expanded contact holes may prevent the formation of conductive bridges between storage node contacts. In particular, where an interlayer insulating layer below a bit line has a stacked structure of insulating layers having different wet etching rates, even if the interlayer insulating layer below the bit line is locally removed during the formation of the expanded contact holes, the contact spacer may prevent the formation of a conductive bridge between the storage node contacts.

Furthermore, as described above, the contact spacer may eliminate exposure of the bit line contact plug caused when the expanded contact holes are formed. Therefore, the contact spacer may prevent the formation of a conductive bridge between the storage node contact and the bit line contact plug.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a semiconductor device, comprising:
forming contact pads in a first insulating layer on a substrate;
forming a second insulating layer on the first insulating layer and on the contact pads;
forming bit lines on the second insulating layer, the bit lines connected to a first plurality of the contact pads by bit line contact plugs;
forming expanded contact holes in the second insulating layer between the bit lines, wherein the expanded contact holes are expanded toward the bit lines; and
forming contact spacers on side walls of the expanded contact holes.

2. The method as claimed in claim 1, wherein the second insulating layer is formed by stacking a first oxide layer on the substrate, stacking an etching stop layer on the first oxide layer, and stacking a second oxide layer on the first oxide layer.

3. The method as claimed in claim 2, wherein forming the expanded contact holes comprises:
anisotropically etching the second insulating layer to expose a second plurality of contact pads; and
isotropically etching the second insulating layer to form expanded portions in the first oxide layer, the first oxide layer having an isotropic etching rate higher than that of the second oxide layer.

4. The method as claimed in claim 2, wherein forming the expanded contact holes comprises:
anisotropically etching the second insulating layer to expose a second plurality of contact pads; and
isotropically etching the second insulating layer to form expanded portions in the first oxide layer and the second oxide layer, the first oxide layer and the second oxide layer having a same isotropic etching rate.

5. The method as claimed in claim 2, wherein forming the expanded contact holes comprises:
anisotropically etching the second oxide layer and the etching stop layer to expose the first oxide layer; and
isotropically etching the first oxide layer to form expanded portions in the first oxide layer, the first oxide layer having an isotropic etching rate higher than that of the second oxide layer.

6. The method as claimed in claim 2, wherein forming the expanded contact holes comprises:
anisotropically etching the second oxide layer and the etching stop layer to expose the first oxide layer; and
isotropically etching the first oxide layer and the second oxide layer to form expanded portions in the first oxide layer and the second oxide layer, the first oxide layer and the second oxide layer having a same isotropic etching rate.

7. The method as claimed in claim 2, wherein forming the expanded contact holes comprises:
anisotropically etching the second oxide layer and the etching stop layer to expose the first oxide layer; and
isotropically etching the second oxide layer to form expanded portions in the second oxide layer, the second oxide layer having an isotropic etching rate higher than that of the first oxide layer.

8. The method as claimed in claim 1, wherein the second insulating layer is formed by stacking a first oxide layer on the substrate and stacking a second oxide layer on the first oxide layer.

9. The method as claimed in claim 8, wherein forming the expanded contact holes comprises:
anisotropically etching the second insulating layer to expose a second plurality of contact pads; and
isotropically etching the first oxide layer to form expanded portions in the first oxide layer, the first oxide layer having an isotropic etching rate higher than that of the second oxide layer.

10. The method as claimed in claim 8, wherein forming the expanded contact holes comprises:
anisotropically etching the second insulating layer to expose a second plurality of contact pads; and
isotropically etching the second oxide layer to form expanded portions in the second oxide layer, the second oxide layer having an isotropic etching rate higher than that of the first oxide layer.

11. The method as claimed in claim 8, wherein forming the expanded contact holes comprises:
anisotropically etching the second oxide layer to expose the first oxide layer; and
isotropically etching the first oxide layer to form expanded portions in the first oxide layer, the first oxide layer having an isotropic etching rate higher than that of the second oxide layer.

12. The method as claimed in claim 8, wherein forming the expanded contact holes comprises:
anisotropically etching the second oxide layer to expose the first oxide layer; and
isotropically etching the second oxide layer to form expanded portions in the second oxide layer, the second oxide layer having an isotropic etching rate higher than that of the first oxide layer.

13. The method as claimed in claim 1, wherein the contact spacers are formed by depositing a conformal insulation layer on a portion of the second insulating layer exposed by the expanded contact holes.

14. The method as claimed in claim 1, further comprising forming a conductive material on contact spacers in adjacent first and second expanded contact holes, wherein:
forming the first and second expanded contact holes includes forming a void in a portion of the second insulating layer between the first and second contact holes such that first and second expanded contact holes are in communication, and
forming the contact spacers isolates the conductive material in the first expanded contact hole from the conductive material in the second expanded contact hole.

15. The method as claimed in claim 1, further comprising forming a conductive material on a contact spacer in an expanded contact hole, wherein:
forming the expanded contact hole exposes a portion of a bit line contact plug, and
forming the contact spacer isolates the bit line contact plug from the conductive material in the expanded contact hole.

16. A semiconductor device, comprising:
contact pads in a first insulating layer on a substrate; a second insulating layer on the first insulating layer and on the contact pads;
bit lines on the second insulating layer, the bit lines connected to a first plurality of the contact pads by bit line contact plugs;
expanded contact holes in the second insulating layer between the bit lines, wherein the expanded contact holes are expanded toward the bit lines; and
contact spacers formed along side walls of the expanded contact holes.

17. The device as claimed in claim 16, wherein the second insulating layer includes an oxide layer, and
the expanded contact holes include expanded portions extending toward the bit lines in the oxide layer.

18. The device as claimed in claim 17, wherein the contact spacers include a conformal insulation layer on the expanded portions.

19. The device as claimed in claim 18, further comprising a conductive material in the expanded contact holes, wherein the contact spacers are disposed between the conductive material and the side walls of the expanded contact holes.

20. The device as claimed in claim 17, wherein the second insulating layer includes at least two layers having different isotropic etching rates.
